(19) United States
(12) Patent Application Publication
(10) Pub. No.: US 2025/0300419 A1
(43) Pub. Date: Sep. 25, 2025

(54) TUNABLE RAMAN PUMP FOR RAMAN AMPLIFICATION

(71) Applicant: II-VI Delaware, Inc., Willmington, DE (US)

(72) Inventors: Ian Peter McClean, Brixham (GB); Nadhum Kadhum Zayer, Devon (GB)

(21) Appl. No.: 18/612,973

(22) Filed: Mar. 21, 2024

(51) Int. Cl. H01S 3/094; H01S 3/067; H01S 3/0941; H01S 3/10; H01S 3/30

(52) U.S. Cl. CPC H01S 3/094096; H01S 3/0675; H01S 3/06762; H01S 3/094003; H01S 3/0941; H01S 3/1001; H01S 3/302

(57) ABSTRACT

A fiber Raman amplifier system that includes a Raman pump module with a first pump laser at a first wavelength and a first power and a second pump laser at a second wavelength and a second power. The second wavelength is less than 10 nanometers different from the first wavelength. A ratio of the first power to the second power is adjusted to establish a Raman gain in a bandwidth.

### BACKGROUND

Fiber Raman Amplifiers (FRAs) are created by transmitting a higher power pump laser into an optical fiber above the threshold for non-linear modification of the refractive index of the fiber. This can result in stimulated energy transfer from the pump laser to an optical signal travelling in the same or opposite direction of the pump signal. FRAs may be used in telecommunication networks by using the transmission span fiber (i.e., distributed Raman) or using a specific fiber (i.e., discrete Raman) as the gain medium. Optical wavelengths (or frequencies) of the higher power pump laser are chosen to provide gain at the necessary optical signal wavelength. For example, a silica based optical fiber has Raman gain about 13 THz from a pump laser wavelength. Higher gain in optical fiber is achieved if pump wavelengths are shorter than the signal. Therefore, to obtain distributed Raman gain at 1550 nm, a pump wavelength needs to be about −100 nm shorter than 1550 nm.

Raman pump wavelengths for telecommunication networks may be around 1420 nm to 1470 nm for amplifying C-band transmissions and 1470 nm to 1520 nm for amplifying L-band transmissions. For amplifications across the C-band or L-band, three or four pump wavelengths may be used for the FRA.

### SUMMARY

In general, embodiments are directed to a FRA system that includes a Raman pump module using at least two different wavelengths. The pump lasers of the Raman module have a small difference in output wavelength to establish a composite spectral output of the module. By changing the ratio of the powers of the pump wavelengths, the Raman module produces an effective wavelength output that may be manipulated over a limited range.

In one aspect, embodiments are directed to a Raman amplifier system that includes a Raman pump module with a first pump laser at a first wavelength and a first power and a second pump laser at a second wavelength and a second power. The second wavelength is less than 10 nanometers different from the first wavelength, and a ratio of the first power to the second power is adjusted to establish a Raman gain in a bandwidth. The system may include other pump lasers and/or Raman modules to establish the gain across the bandwidth. The bandwidth may be the C-band region and/or the L-band regions for telecommunications applications. Due to the wavelength independence nature of Raman amplification in optical fibers the bandwidth could also be any optical bandwidth used in telecommunications, such as O-band, S-band, U-band and so on.

The Raman amplifier system may also include a third pump laser at a third wavelength and a third power, the third wavelength being different from the second wavelength and less than 10 nanometers different from the first wavelength.

The ratio of the first power to the second power may be adjusted based on feedback from the amplified signal and/or using machine learning and artificial intelligence techniques.

In another aspect, embodiments are related to a method optimizing Raman gain that includes transmitting a first pump laser at a first wavelength and a first power and transmitting a second pump laser at a second wavelength and a second power. The second wavelength is less than 10 nanometers different from the first wavelength. The method also includes adjusting a ratio of the first power to the second power to establish a Raman gain in a bandwidth.

The method may include transmitting other pump lasers and/or Raman modules to establish the gain across the bandwidth. The bandwidth may be the C-band region or the L-band regions for telecommunications applications. Due to the wavelength independent nature of Raman amplification in optical fibers, the bandwidth could also be any optical bandwidth used in telecommunications, such as O-band, S-band, U-band and so on.

The method may also include a third pump laser at a third wavelength and a third power, the third wavelength being different from the second wavelength and less than 10 nanometers different from the first wavelength.

The ratio of the first power to the second power may be adjusted based on feedback from the amplified signal and/or using machine learning and artificial intelligence techniques.

This summary is intended to provide a brief overview of some of the subject matter described in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF DRAWINGS

A better understanding of the present subject matter can be obtained when the following detailed description of various aspects is considered in conjunction with the following drawings.

FIG. 1A illustrates a general Raman system in accordance with one or more embodiments. FIG. 1B illustrates a schematic of a Raman pump module in accordance with one or more embodiments herein.

FIG. 2 illustrates a Raman gain in accordance with one or more embodiments herein.

FIG. 3 illustrates a relative change in the Raman gain using the parameters of FIG. 2, in accordance with one or more embodiments herein.

FIGS. 4A, 4B, and 4C illustrate an example in accordance with embodiments herein.

FIGS. 5A, 5B, and 5C illustrate examples of different Raman modules in accordance with embodiments herein.

FIG. 6 illustrates another example of a Raman pump module in accordance with one or more embodiments herein.

While the features described herein may be susceptible to various modifications and alternative forms, specific aspects thereof are shown by way of example in the drawings and are herein described in detail. It should be understood, however, that the drawings and detailed description thereto are not intended to be limiting to the particular samples disclosed, but on the contrary, the intention is to cover all modifications, equivalents and alternatives falling within the spirit and scope of the subject matter as defined by the appended claims.

### DETAILED DESCRIPTION

As noted above, in telecommunication applications, a consistent Raman gain is desired over an approximate 40 nm range of wavelengths for the C-band and L-bands. Also, communications are expected to extend into C++ and L++ bands in the future, and the frequencies used for telecommunications will likely continue to evolve to bands such as O- and, S-band and U-band. In order to establish a consistent Raman gain over the desired bandwidths, FRAs use multiple pump wavelengths that are coupled together. The pump wavelengths may be propagated or counter-propagated relative to the data signals through a length of the fiber.

A typical FRA system may include three or four fixed pump wavelength lasers combined based on the spectral range for amplification and the characteristics of the fiber. The (fixed) pump wavelengths have the necessary optical power in each wavelength to provide Raman gain with the goal of providing a flat, consistent gain across all the signal channels. In some systems, the pump wavelength is established by coupling two lasers at the same wavelength to obtain the necessary output power. The two lasers are typically multiplexed with a 450 angle splice into a polarization beam combining component to depolarize the pump wavelength. In such systems, the identicality of the lasers helps to ensure that the depolarization occurs adequately.

However, there are a large number of parameters that can affect the Raman gain over a bandwidth. For example, there may be shifts of a grating center wavelength during manufacturing, the age and/or temperature of the fiber will affect the Raman response, as well as the specific make-up of the optical signals, or channels, to be amplified. Further, the Raman gain is the result of a stimulated Raman emission process from all the pump lasers. Given the large number of parameters, as well as the stokes and anti-stokes contributions from multiple pump wavelengths, the Raman gain over a bandwidth is difficult to predict or control.

In typical FRA systems for bandwidth amplification, the pump wavelengths are fixed, and a user may only adjust the output power at the different pump wavelengths to control the Raman gain over the bandwidth. Optical channel monitors or channel receivers can measure the channel gain during operation. Although adjusting the output power of one or more of the fixed-wavelength pump lasers will affect the Raman gain, the changes are interactive and difficult to control to an optimum condition.

To elaborate further, the power of a shorter wavelength pump can contribute to the Raman gain associated with the longer wavelength pumps. As such, adjusting the power of a shorter wavelength pump changes the effective power in the fiber at the longer wavelengths. Also, adjusting the power of a longer wavelength pump changes the effective power contribution from shorter wavelength pumps. In a system with four pump wavelengths, each wavelength effectively passes light to another wavelength in different proportions based on the wavelength spacing. Thus, changing one pump wavelength power changes the effective power in the other three wavelengths, which in turn causes more changes to the effective powers of the four wavelengths, and so on. Although such gain transfers may be small compared to the gain from a single wavelength, optimization of Raman gain over a bandwidth can be difficult in view of the above. Thus, typical FRA systems are designed for a specific operating case.

Disclosed Raman amplifier systems and methods provide for additional control of the Raman gain across the desired bandwidth by providing limited tunability at a particular pump wavelength, which is advantageous. The ability to fine tune a pump laser wavelength over a limited range can help to establish, or maintain, a relatively flat Raman gain across a desired bandwidth to overcome variance in the overall system. Such control may also be used to manipulate the shape of the Raman gain in view of the specific channels to be amplified.

Embodiments disclosed herein provide a FRA system that includes a Raman pump module using at least two different wavelengths. The pump lasers of the Raman module have a small difference in output wavelength to establish a composite spectral output of the module. By changing the ratio of the powers of the pump wavelengths, the Raman module produces an effective wavelength output that may be manipulated over a limited range.

The Raman pump module may be combined with additional wavelengths, or additional Raman pump modules, to establish the Raman gain profile over the desired bandwidth of a fiber. Embodiments advantageously provide a system and techniques for further tuning the Raman gain over the desired bandwidth.

In embodiments, the amplified signals, or portions of the amplified signals, may be monitored to provide feedback to control the output power of the lasers used. In some embodiments, machine learning and artificial intelligence techniques may be used to further tune the Raman pumping to optimize the Raman gain in desired bandwidths during live transmissions.

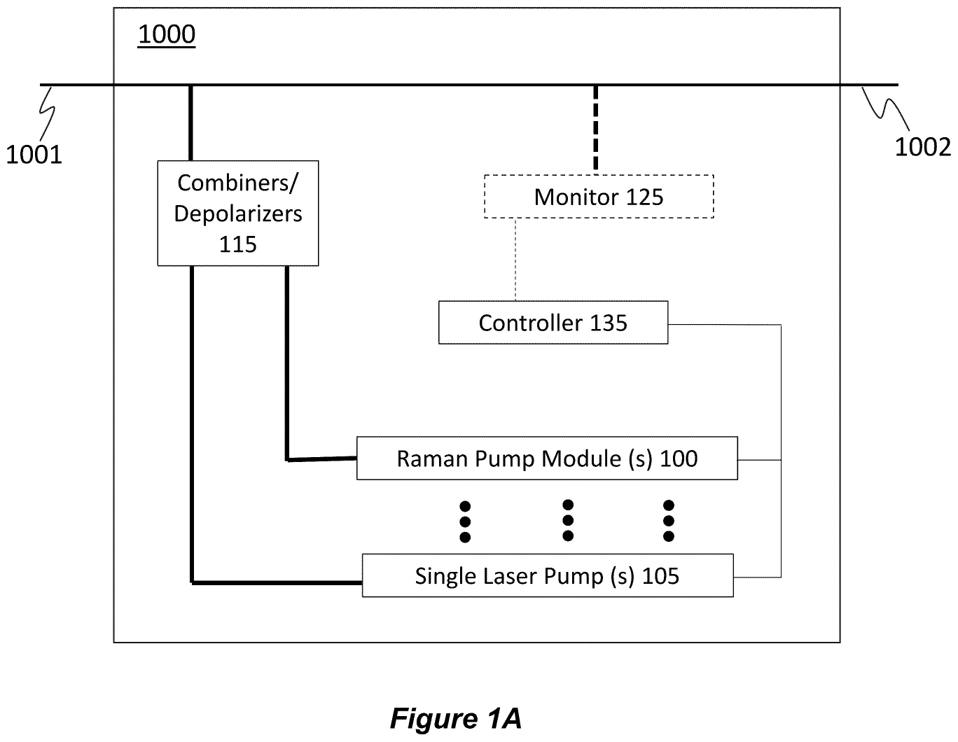

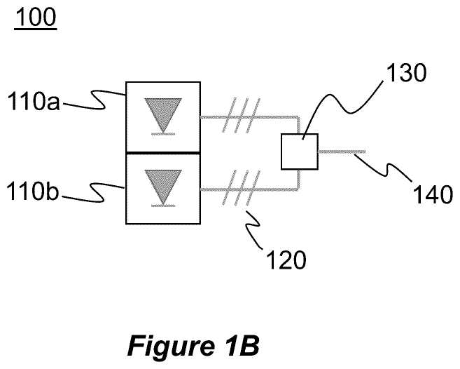

FIG. 1A illustrates a general Raman system in accordance with one or more embodiments. In FIG. 1A, an input signal 1001 enters the Raman system 1000, and an amplified signal exits 1002 the Raman system 1000. The Raman system 1000 includes one or more Raman modules 100 in accordance with embodiments herein and may include other single laser pump multiple lasers 105. Although a Raman module may include its own combiner/depolarizer in accordance with some embodiments, the collective pump wavelengths 100, 105 are combined and depolarized using optical components in the Combiners/Depolarizers 115. The collective pump wavelengths 100, 105 are then incorporated into the input signals 1001. The collective pump wavelengths 100, 105 are counter-propagated, relative to the input signals 1001.

The Raman system 1000 includes a controller 135 that controls a total power and a ratio of relative powers in the one or more Raman Pump Module(s) 100. The controller also controls the output power of any Single Laser Pump(s) 105 included in the Raman system 1000. The Raman system 1000 may include a Monitor 125 that measures the amplified signals, or portions of the amplified signals, in order to evaluate the Raman gain and provide feedback to the controller 135. The Raman system 1000 shown in FIG. 1A counter-propagates the pump wavelengths 100, 105 relative to the input signal 1001; however, embodiments may also include the pump wavelengths propagating in the same direction as the input signals. Such embodiments may include a monitor located at the end of the fiber, to determine the Raman gain.

The Raman system 1000 is not limited to the above components in a single package. For example, the Monitor 125 and/or the Controller 135 may be separate packages. In some embodiments, the Controller 135 may include a processor for analyzing data from the Monitor 125 and adjusting the associated powers of the collective pump wavelengths 100, 105. The Controller 135 may be in communication with one or more outside systems to monitor, analyze, and determine appropriate adjustments to the associated powers of the collective pump wavelengths 100, 105. Such adjustments may be dictated through the use of machine learning techniques, or artificial intelligence techniques.

FIG. 1B illustrates a schematic of a Raman pump module in accordance with one or more embodiments herein. The Raman pump module 100 includes two lasers 110a, 110b, with a small (less than 10 nm) difference in wavelength output. The Raman pump module 100 includes a Fiber Bragg Grating (FBG) 120 for each laser 110a, 110b, and a beam combining component 130, which may be a polarizing beam combining component 130. The FBG provides appropriate feedback for the particular desired wavelength to “lock” the output of the respective laser to that wavelength. The polarizing beam combining component 130 multiplexes the polarized output of the lasers 110a, 110b, which can be depolarized in a subsequent component. The output fiber 140 of the Raman module 100 may be combined with other lasers or Raman modules before being counter-propagated through a fiber for Raman amplification.

The difference in wavelength between the laser 110a and the laser 110b may be less than 10 nm. In some embodiments, the difference in wavelength may be established based on the beam combining component 130. That is, the difference in wavelength between the laser 110a and the laser 110b may be selected to be small enough so that the polarizing beam combining component 130 used is substantially similar to a combining component used to combine laser sources of the same wavelength. With identical wavelengths, the output of such polarizing beam components is depolarized light with approximately twice the power. If the wavelengths are not identical, some level of polarization may be present. Embodiments include wavelength differences that may still use such polarizing beam components. Alternatively, the beams may be combined and depolarization may be done in a subsequent component.

By controlling a ratio of the power output of for the lasers 110a, 110b, the predominately nonpolarized wavelength output from the polarizing beam combining component 130 may be effectively tuned over a small range (±1-4 nm) of wavelengths resulting in tunable Raman pump laser. This output is then combined with other the Raman pump wavelengths to establish the overall Raman gain over a bandwidth. In some embodiments, the bandwidth may be greater than 30 nm.

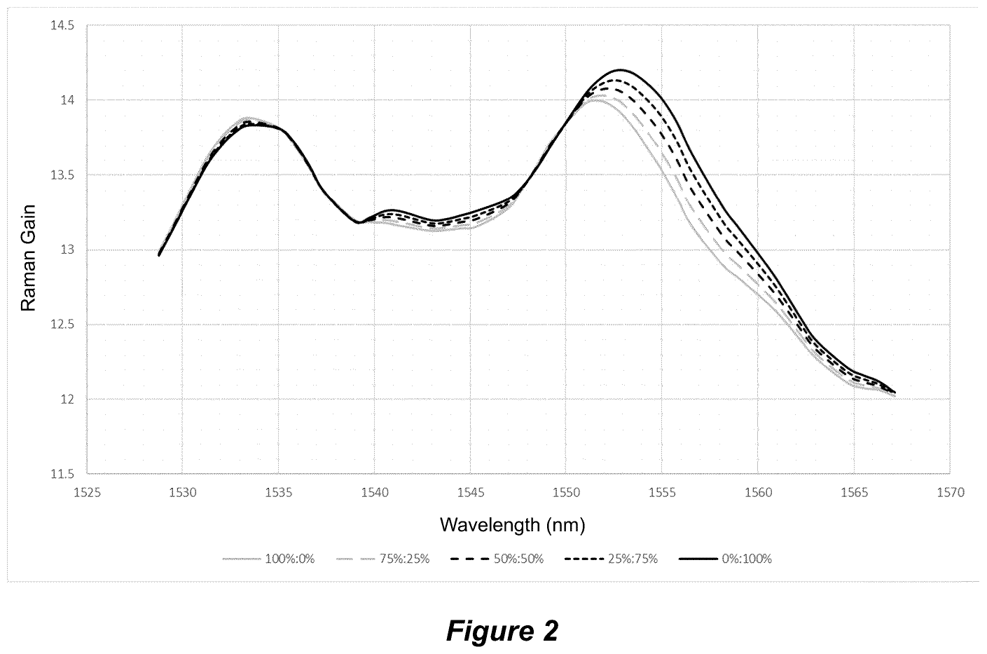

FIG. 2 illustrates a Raman gain in accordance with one or more embodiments herein. In FIG. 2, a Raman module includes two lasers with an output of 1441 nm and 1442 nm. The Raman system also includes lasers at 1422 nm and 1465 nm to provide Raman amplification in the 1530 nm to 1560 nm range. In FIG. 2, the Raman gain is shown for different ratios of the power of the 1441 nm laser to the power of 1442 nm laser. Specifically, the Raman gain is shown for 100:0, 75:25, 50:50, 25:75, and 0:100 ratios of the percentage power of 1441 nm laser to the 1442 nm laser.

As can be seen, there is a small spectral shift in the Raman gain in the 1550-1555 nm range as a result of the varying power. This effectively provides a small wavelength tuning of the Raman excitation source which is used to fine tune Raman gain in accordance with embodiments herein. This provides a novel way to manipulate the Raman gain to obtain a relatively flat gain over a range of wavelengths (i.e., the desired bandwidth). This may also be used to fine tune the Raman gain to specific channels in a fiber, if desired.

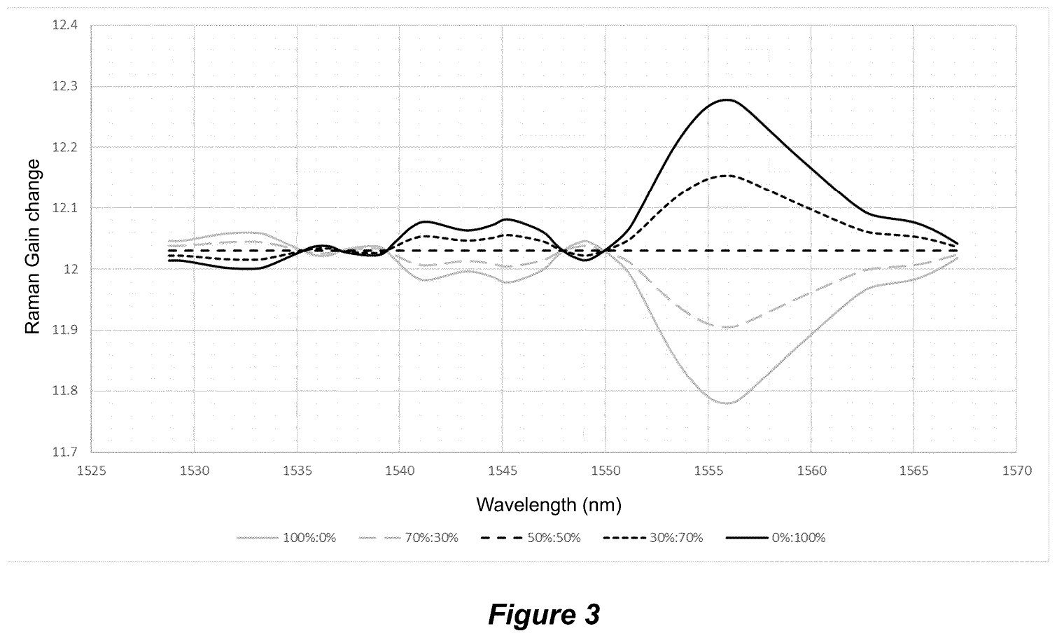

FIG. 3 illustrates a relative change in the Raman gain using the parameters of FIG. 2, in accordance with one or more embodiments herein. FIG. 3 is shown to illustrate how the different ratios of the power of the lasers from a Raman module can affect the Raman gain. As can be seen, varying the percentage power ratio of the 1441/1442 nm lasers can fine tune the Raman response in the 1550-1560 nm range, as well as other regions of the Raman gain.

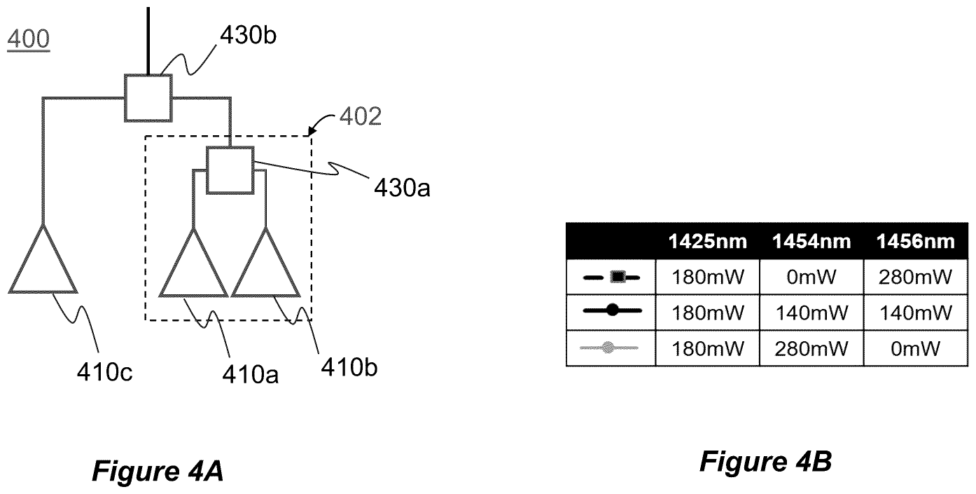

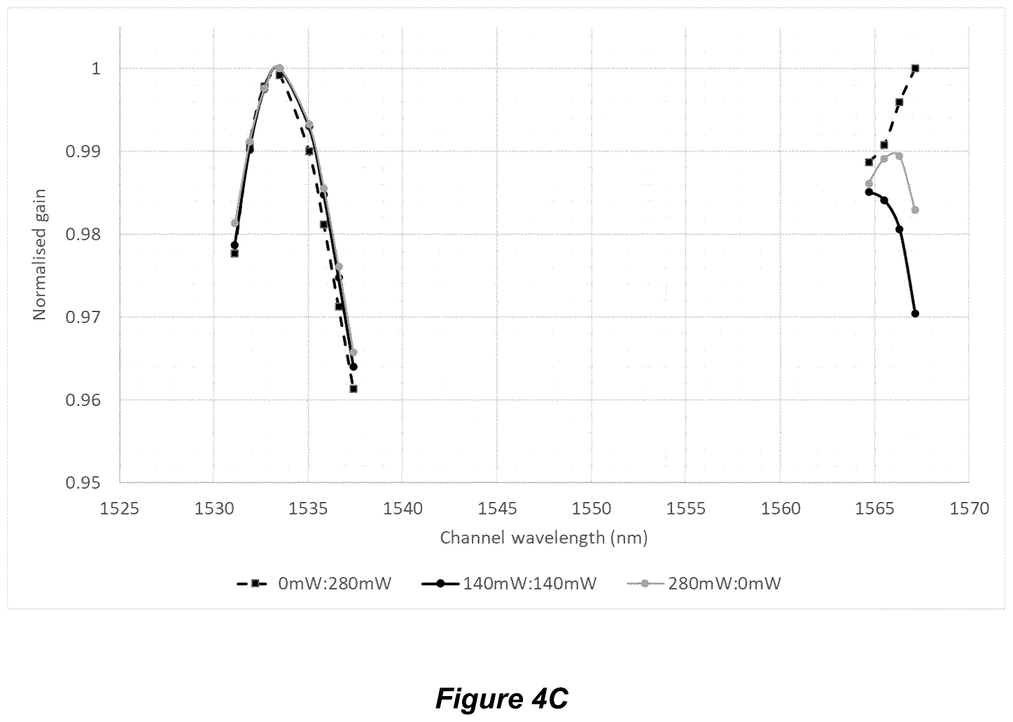

FIGS. 4A, 4B, and 4C illustrate an example in accordance with embodiments herein. FIG. 4A is a schematic of the example Raman amplification system 400 in accordance with one or more embodiments. The Raman amplification system 400 includes, for example, three lasers 410a, 410b, and 410c. The Raman laser 410a and Raman laser 410b are part of a Raman module 402. The Raman laser 410a has a wavelength of, for example, 1454 nm, and the Raman laser 410b has a wavelength of, for example, 1456 nm. The Raman lasers 410a, 410b are combined in the beam combining component 430a, similar to FIG. 1B.

The Raman amplification system 400 also includes a fixed Raman pump laser 410c at 1425 nm. The output of the Raman pump laser 410c is coupled to the output of the Raman module 402 using the beam combining component 430b. The beam combining components 430a, 430b may be similar or different components. The beam combining component 430b may help depolarize the pump lasers. In some embodiments, the beam combining component 403a may be a polarization beam combining component multiplexed with a 450 angle splice.

FIG. 4B is a legend that shows the power of the laser 410c, as well as the different power ratios of lasers 410a, 410b in the Raman gain shown in FIG. 4C. The examples in FIGS. 4B-4C demonstrate percentage power ratios 0:100, 50:50, and 100:0 of the 1454 nm to 1456 nm lasers 410a, 410b.

In the examples of FIGS. 4A-4C, the longer wavelength of the Raman amplification system is engineered to be shifted by altering the power ratio of the lasers 410a, 410b. This may be beneficial in a case where there are a few longer wavelength channels to be amplified in a fiber.

FIG. 4C shows a normalized Raman gain for different power ratios of FIG. 4B, in accordance with embodiments herein. As shown, there are some minimal changes to the Raman gain around 1535 nm by tuning the ratio of the powers of the lasers 410a, 410b; however, at the longer wavelength channels around 1565 nm, the slope of the gain tilt changes from positive to negative. Because the gain contributions are unpredictable, having a tunable pump laser provides for additional advantages for generating the desired Raman gain. Accordingly, if there are wavelength channels in the 1565 nm range to be amplified, this example provides a novel control over the Raman amplification at those channels.

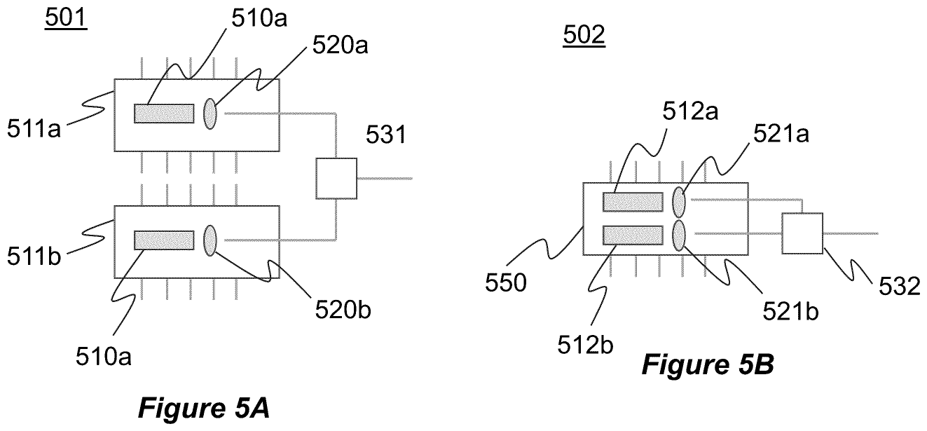

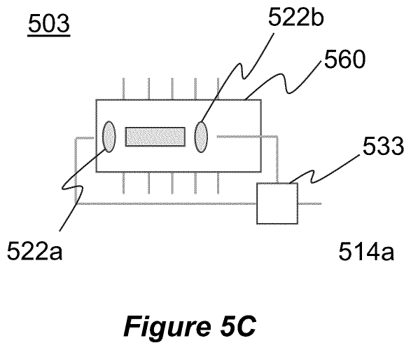

In accordance with embodiments, the Raman module may include different kinds of semiconductor lasers and arrangements. FIGS. 5A, 5B, and 5C illustrate examples of different Raman modules in accordance with embodiments herein. In the example of FIG. 5A, the two wavelengths are sourced from two separate semiconducting pump lasers, similar to the previous examples above. The Raman module 501 includes two separate semiconducting laser chips 511a, 511b, that each include a laser FBG 520a, 520b to lock the wavelength. The Raman module 501 also includes a beam combining component 531.

In the example of FIG. 5B, the Raman module 502 uses a dual chip laser 550. The dual chip laser includes the two lasers 512a, 512b housed in a single package, with each laser having an FBG 521a, 521b to lock the wavelength. The Raman module 502 also includes a beam combining component 532.

In the example of FIG. 5C, the Raman module 503 includes a two-sided emission pump laser chip 560. Each side of the two-sided emission pump laser chip 560 has a separate drive current control and FBG 522a, 522b to lock the different wavelengths (see, for example, U.S. Pat. No. 11,652,332, the contents of which are hereby in corporate by reference). As in previous embodiments, the Raman module 503 also includes a beam combining component 533, similar to those described previously.

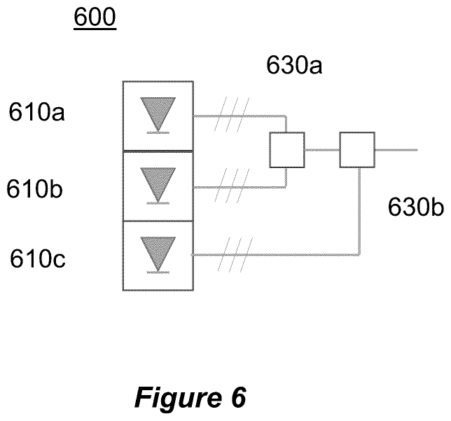

FIG. 6 illustrates another example of a Raman pump module in accordance with one or more embodiments herein. In the example of FIG. 6, the Raman pump module 600 includes three lasers 610a, 610b, 610c. In these embodiments, two of the lasers have a wavelength a small step (less than 10 nm) from the third laser. For example, laser 610a has a wavelength of X nm; and lasers 610b and 610c have a wavelength of X+Y nm and X-Y nm, respectively. In some embodiments, the ratio of the power of two of the three lasers may be adjusted, similar to embodiments. The use of three lasers may provide a wider wavelength tuning range and the ability to further fine tune the Raman gain in accordance with the bandwidth and/or selected channels.

Given the use of the adjustable power ratios described herein, in combination with power adjustments of the other pump sources, the bandwidth range, the specific channels, as well as the other factors such as temperature/age, etc., one of ordinary skill in the art will appreciate the large parameter space that can affect the Raman gain.

As previously noted, feedback from a monitor may be used to optimize the power of the pump wavelengths during operation. Accordingly, embodiments disclosed herein may employ machine learning or artificial intelligence techniques based on the feedback and the known parameters in the space. Embodiments may use such feedback in conjunction with machine learning techniques to learn an appropriate laser power ratio and gain shape under multiple operating conditions.

Embodiments may further employ artificial intelligence to manage the machine learning and/or develop training models based on the feedback and details of the parameter space. The artificial intelligence may use learned/model information to establish the appropriate power ratios, pump wavelengths, etc. for the desired operating conditions across the entire bandwidth.

Embodiments disclosed herein provide a Raman amplifier with an advantageous tuning that can effectively shift a Raman pump wavelength by a few nanometers. Embodiments provide a novel way to further fine-tune the Raman gain across the bandwidth based on the operating conditions and the channels to be amplified. Embodiments may provide a composite Raman gain (i.e., a sum of the gains created from each pump wavelength) that may be manipulated to get a composite wider gain with the best gain flatness. Embodiments may be used to manipulate the gain flatness per pump wavelength in at least a portion of the overall gain bandwidth to create an optimized gain that is unachievable using fixed pump wavelengths.

The examples described herein have been described with reference to the accompanying figures. Modifications and alterations will occur to others upon reading and understanding the foregoing examples. Accordingly, the foregoing examples are not to be construed as limiting the present disclosure.

Although the aspects above have been described in considerable detail, numerous variations and modifications will become apparent to those skilled in the art once the above disclosure is fully appreciated. It is intended that the following claims be interpreted to embrace all such variations and modifications.

What is claimed is:

1. A fiber Raman amplifier system, comprising:
an adjustable Raman pump module having an adjustable composite output, the adjustable Raman pump module comprising:
a first pump laser at a first wavelength and a first power;
a second pump laser at a second wavelength and a second power,
wherein the second wavelength is less than 10 nanometers different from the first wavelength, and
wherein a ratio of the first power to the second power is adjustable to provide an adjustable composite output, the adjustable composite output establishing a specified Raman gain in a bandwidth.

2. The system of claim 1, further comprising:
a third pump laser at a third wavelength and a fourth pump laser at a fourth wavelength.

3. The system of claim 1, wherein the bandwidth is the C-band region or the L-band region.

4. The system of claim 1, the Raman module further comprising:
a polarization beam combining component, wherein the first pump laser and the second pump laser are multiplexed with a 45° angle splice into a polarization beam combining component.

5. The system of claim 1, further comprising:
a third pump laser at a third wavelength and a third power, wherein the third wavelength is different from the second wavelength and less than 10 nanometers different from the first wavelength.

6. The system of claim 1, wherein the Raman module comprises a dual chip laser including the first pump laser and the second pump laser, and the Raman module further comprises:
a first Fiber Bragg Grating (FBG) coupled to the first pump laser; and
a second FBG coupled to the second pump laser.

7. The system of claim 1, wherein the Raman module comprises a two side emission laser chip including the first pump laser and the second pump laser, and the Raman module further comprises:
a first Fiber Bragg Grating (FBG) coupled to the first pump laser;
a second FBG coupled to the second pump laser; and
an independent drive control for adjusting the first power and the second power to establish the ratio.

8. The system of claim 1, wherein the ratio of the first power to the second power is output based on machine learning or artificial intelligence techniques.

9. The system of claim 1, wherein the ratio of the first power to the second power is output based on feedback from an amplified signal.

10. The system of claim 1, wherein the ratio of the first power to the second power is output based on a wavelength of a channel to be amplified in a fiber.

11. The system of claim 1, wherein the Raman gain varies by less than 10% over the bandwidth.

12. A method of optimizing Raman gain, the method comprising:
transmitting a first pump laser at a first wavelength and a first power;
transmitting a second pump laser at a second wavelength and a second power,
wherein the second wavelength is less than 10 nanometers different from the first wavelength;
adjusting a ratio of the first power to the second power to provide an adjustable composite output, the adjustable composite output establishing a specified Raman gain in a bandwidth.

13. The method of claim 12, further comprising:
transmitting a third pump laser at a third wavelength and a fourth pump laser at a fourth wavelength.

14. The method of claim 12, wherein the bandwidth is the C-band region or the L-band region.

15. The method of claim 12, further comprising:
transmitting a third pump laser at a third wavelength and a third power, wherein the third wavelength is different from the second wavelength and less than 10 nanometers different from the first wavelength.

16. The method of claim 12, wherein the ratio of the first power to the second power is output based on machine learning or artificial intelligence techniques.

17. The method of claim 12, wherein the ratio of the first power to the second power is output based on feedback from an amplified signal.

18. The method of claim 12, wherein the ratio of the first power to the second power is output based on a wavelength of a channel to be amplified in a fiber.
